(19) United States
(12) Patent Application Publication
(10) Pub. No.: US 2026/0260481 A1
(43) Pub. Date: Sep. 3, 2026

(54) METHOD FOR DETECTING POTENTIAL ERRORS IN DIGITALLY SEGMENTED IMAGES, AND A SYSTEM EMPLOYING THE SAME

(71) Applicant: TECHINSIGHTS INC., Ottawa (CA)

(72) Inventors: Christopher PAWLOWICZ, Ottawa (CA); Michael GREEN, Nepean (CA); Bruno MACHADO TRINDADE, Kanata (CA); Fengbo REN, Chandler, AZ (US); Zhikang ZHANG, Tempe, AZ (US); Zifan YU, Tempe, AZ (US)

(21) Appl. No.: 19/123,990

(22) PCT Filed: Oct. 24, 2023
(86) PCT No.: PCT/CA2023/051412

§ 371 Date: Apr. 24, 2025

Related U.S. Application Data
(60) Provisional application No. 63/380,843, filed on Oct. 25, 2022.

(51) Int. Cl. G06V 10/98; G06T 5/50; G06T 7/10

(52) U.S. Cl. CPC G06V 10/98; G06T 5/50; G06T 7/10; G06T 2207/20221

(57) ABSTRACT

A method for detecting potential errors in digitally segmented images, and a system employing the same. In one embodiment, a method includes receiving as input a segmented image including an array of segmented pixel values; for each of at least one respective dimension of the array, calculating a respective extension array including, for each given pixel of the array corresponding with a designated segmentation value, a corresponding extension value; based at least in part on the array of segmented pixel values and each respective extension array, identifying, via a digital image classifier and a trained error detection model accessible thereto, a potential error in the segmented image; and upon positively identifying the potential error, providing a corresponding error signal in association with the segmented image.

### CROSS REFERENCE TO RELATED APPLICATIONS

This application claims priority to U.S. Provisional Application No. 63/380,843 filed Oct. 25, 2022, the entire contents of which are hereby incorporated herein by reference.

### FIELD OF THE DISCLOSURE

The present disclosure relates to digital image recognition, and, in particular, to a method for detecting potential errors in digitally segmented images, and a system employing the same.

### BACKGROUND

Existing techniques of integrated circuit (IC) segmentation are generally performed on scanning electron microscopy (SEM) images to extract original IC designs for analysis. Due to the complicated nanoscale structures of current ICs and low error tolerance of the task, existing automated SEM image segmentation approaches typically require human experts to perform post-extraction visual inspection of segmentation results to ensure accuracy. Such manual inspections can be highly challenging and time consuming, as the number of images that are processed for various tasks can range from thousands to millions. Accordingly, inspection of processed images can often be a bottleneck for large scale industrial applications.

Machine learning platforms offer a potential solution for improving the automation of image recognition. For example, Lin et al. (Lin, et al., ‘Deep Learning-Based Image Analysis Framework for Hardware Assurance of Digital Integrated Circuits’, 2020 IEEE International Symposium on the Physical and Failure Analysis of Integrated Circuits (IPFA), pp. 1-6, DOI: 10.1109/IPFA49335.2020.9261081, 2020) discloses a deep learning-based approach for recognising electrical components in images, wherein a fully convolutional network is used to perform segmentation with respect to both vias and metal lines of SEM images of ICs.

More generally, machine learning-based image recognition processes typically receive raw images as input, and attempt to infer properties and/or identify features therefrom. Such approaches are limited by, for example, the quality and/or accuracy of raw data, and may not perform well for some applications, such as the extraction of IC features from SEM images, which are inherently noisy and highly variable from image to image.

Some machine learning platforms are specifically configured to synthesise images that may appear ‘realistic’ to a human based on input data. For example, pix2pix is a machine learning architecture that uses a conditional generative adversarial network (cGAN) that learns a mapping from input images to output images. However, pix2pix is not application-specific. That is, it can be applied to a wide range of tasks, such as synthesising photos from label maps and generating colourised photos from black and white images. While potentially useful for some generalised applications, neither it nor comparable platforms may be suitable for some specialised tasks, including the accurate identification of circuit features from SEM images.

This background information is provided to reveal information believed by the applicant to be of possible relevance. No admission is necessarily intended, nor should be construed, that any of the preceding information constitutes prior art or forms part of the general common knowledge in the relevant art.

### SUMMARY

The following presents a simplified summary of the general inventive concept(s) described herein to provide a basic understanding of some aspects of the disclosure. This summary is not an extensive overview of the disclosure. It is not intended to restrict key or critical elements of embodiments of the disclosure or to delineate their scope beyond that which is explicitly or implicitly described by the following description and claims.

A need exists for a method for detecting potential errors in digitally segmented images, and a system employing the same that overcome some of the drawbacks of known techniques, or at least, provides a useful alternative thereto. Some aspects of this disclosure provide examples of such systems and methods.

In accordance with one aspect, there is provided a method for automatically detecting potential errors in segmented images, the method executable by one or more digital data processors and comprising: receiving as input a segmented image comprising an array of segmented pixel values each calculated in respect of a corresponding portion of an image; for each of at least one respective dimension of the array, calculating a respective extension array comprising, for each given pixel of the array corresponding with a designated segmentation value, a corresponding extension value representative of an extension of the designated segmentation value in the respective dimension in the array of segmented pixel values; based at least in part on the array of segmented pixel values and each the respective extension array, identifying, via a digital image classifier and a trained error detection model accessible thereto, a potential error in the segmented image; and upon positively identifying the potential error, providing a corresponding error signal in association with the segmented image.

In one embodiment, the method comprises defining, from each of the array of segmented pixel values and at least one the respective extension array, a corresponding sub-array corresponding with a designated sub-region of the image, wherein the identifying a potential error is digitally executed based at least in part on each the sub-array.

In one embodiment, the providing a corresponding error signal comprises providing the corresponding error signal in association with the corresponding sub-array defined from the array of segmented pixel values.

In one embodiment, the image comprises one or more of a non-optical microscopy image, an electric microscopy image, or a scanning electron microscope (SEM) image.

In one embodiment, one or more of the segmented pixel values or the designated segmentation value corresponds to one or more of a background, a wire, or a via.

In one embodiment, the designated segmentation value corresponds with a pixel value associated with a wire in a SEM image.

In one embodiment, the array of segmented pixel values comprises a two-dimensional array, and wherein the at least one respective dimension of the array comprises both dimensions of the two-dimensional array.

In one embodiment, the extension of the designated segmentation value corresponds with one or more of a number of continuous pixels in the respective dimension sharing the designated segmentation value and comprising the given pixel, or a function thereof.

In one embodiment, the corresponding extension value comprises a normalised extension value representative of the extension of the designated segmentation value normalised by a maximum extension value in the respective extension array.

In one embodiment, the method comprises digitally stacking the array of segmented pixel values and each the respective extension array as a digital representation thereof, wherein the identifying a potential error in the segmented image is executed at least in part based on the digital representation.

In one embodiment, the digital representation comprises a three-layer image stack.

In one embodiment, the digital image classifier comprises a machine learning architecture.

In one embodiment, the machine learning architecture comprises a ResNet-based architecture.

In one embodiment, the identifying a potential error in the segmented image comprises post-processing outputs of the digital image classifier corresponding with respective segmented images corresponding with respective patches of the image, wherein the post-processing comprises detecting error values in relation to a threshold when applied to at least partially overlapping outputs.

In one embodiment, the corresponding error signal is provided in association with an overlap region of the at least partially overlapping outputs.

In accordance with another aspect, there is provided a method for automatically detecting potential errors in segmented images, the method executable by one or more digital data processors and comprising: receiving as input at least one segmented image each comprising a respective array of segmented pixel values each calculated in respect of a corresponding portion of an input image; based at least in part on the segmented pixel values and the input image, digitally translating, using a digital image-to-image translator, the at least one segmented image to a reconstructed image; digitally executing a comparison of the reconstructed image and the input image; based at least in part on the comparison, digitally identifying a region of disparity between the reconstructed image and the input image in accordance with a designated comparison function; and upon positively identifying the region of disparity, providing a corresponding error signal in association with one or more of the at least one segmented image.

In one embodiment, the at least one segmented image comprises a plurality of segmented images.

In one embodiment, the method comprises digitally combining the plurality of segmented images to a combined segmented image, wherein the digitally translating comprises digitally translating the combined segmented image to the reconstructed image.

In one embodiment, the method comprises digitally assigning the segmented values to normalised segmentation values based at least in part on pixel values associated with the input image, wherein the digitally translating comprises digitally translating the at least one segmented image to a reconstructed image based at least in part on the normalised segmentation values.

In one embodiment, the at least one segmented image corresponds with a portion of a larger segmented image.

In one embodiment, the method comprises defining the at least one segmented image from the larger segmented image.

In one embodiment, the input image comprises one or more of a non-optical microscopy image, an electron microscopy image, or a scanning electron microscope (SEM) image.

In one embodiment, the segmented pixel values correspond to one or more of a background, a wire, or a via.

In one embodiment, the at least one of the segmented pixel values corresponds with a pixel value associated with a via in an SEM image.

In one embodiment, the digital image-to-image translator comprises a machine learning architecture.

In one embodiment, the machine learning architecture comprises an adversarial network.

In one embodiment, the comparison comprises a computation of a difference between corresponding pixel values of the input image and the reconstructed image.

In one embodiment, the method comprises digitally defining the region of disparity based at least in part on a computed property of the disparity.

In one embodiment, the designated comparison function comprises one or more comparison threshold parameters corresponding to one or more of a size of the region of disparity or a characteristic metric of pixel values in the region of disparity.

In one embodiment, the digitally identifying a region of disparity comprises digitally filtering the region of disparity based at least in part on the designated comparison function.

In accordance with another aspect, there is provided a method for automatically detecting potential errors in segmented images, the method executable by one or more digital data processors and comprising: receiving as input at least one segmented image each comprising a respective array of segmented pixel values each calculated in respect of a corresponding portion of an input image; identifying a first error type by: for a given one of the at least one segmented image, calculating an extension array in at least one dimension of the respective array of segmented pixel values; and based at least in part on the given segmented image and the extension array, identifying, via a digital image classifier and a trained error detection model accessible thereto, a potential error in the given segmented image; identifying a second error type by: digitally translating, using a digital image-to-image translator, the at least one segmented image to a reconstructed image; and digitally executing a comparison of the reconstructed image and the input image to digitally identify therefrom a region of disparity therebetween in accordance with a designated comparison function; and upon positively identifying one or more of the region of disparity or the potential error, providing a corresponding error signal in association with a corresponding one or more of the at least one segmented image.

In accordance with another aspect, there is provided a non-transitory computer-readable medium having digital instructions stored thereon to be executed by one or more digital processors of a computing platform for automatically detecting potential errors in segmented images by implementing a method as substantially herein described.

In accordance with another aspect, there is provided a system for automatically detecting potential errors in segmented images, the system comprising a computer-readable medium configured for implementing a method as substantially herein described; one or more digital processors; and a network interface configured to directly or indirectly interface over a data network with the computer-readable medium and the one or more digital processors.

Other aspects, features and/or advantages will become more apparent upon reading of the following non-restrictive description of specific embodiments thereof, given by way of example only with reference to the accompanying drawings.

### BRIEF DESCRIPTION OF THE FIGURES

Several embodiments of the present disclosure will be provided, by way of examples only, with reference to the appended drawings, wherein:

FIGS. 1A to 1F are exemplary SEM images and corresponding segmentation results highlighting various potential challenges with digital segmentation tasks, in accordance with various embodiments;

FIG. 2 is a flow diagram illustrating an exemplary process for identifying potential errors in segmented images, in accordance with some embodiments;

FIG. 3 is a flow diagram illustrating an exemplary alternative process for identifying potential errors in segmented images, which may optionally be employed distinctly or in conjunction with the process of FIG. 2, in accordance with some embodiments; and

FIGS. 4A and 4B are graphs illustrating exemplary results obtained for the identification of potential errors in segmented image using the exemplary process of FIG. 3, in accordance with one embodiment.

Elements in the several figures are illustrated for simplicity and clarity and have not necessarily been drawn to scale. For example, the dimensions of some of the elements in the figures may be emphasized relative to other elements for facilitating understanding of the various presently disclosed embodiments. Also, common, but well-understood elements that are useful or necessary in commercially feasible embodiments are often not depicted in order to facilitate a less obstructed view of these various embodiments of the present disclosure.

### DETAILED DESCRIPTION

Various implementations and aspects of the specification will be described with reference to details discussed below. The following description and drawings are illustrative of the specification and are not to be construed as limiting the specification. Numerous specific details are described to provide a thorough understanding of various implementations of the present specification. However, in certain instances, well-known or conventional details are not described in order to provide a concise discussion of implementations of the present specification.

Various apparatuses and processes will be described below to provide examples of implementations of the system disclosed herein. No implementation described below limits any claimed implementation and any claimed implementations may cover processes or apparatuses that differ from those described below. The claimed implementations are not limited to apparatuses or processes having all of the features of any one apparatus or process described below or to features common to multiple or all of the apparatuses or processes described below. It is possible that an apparatus or process described below is not an implementation of any claimed subject matter.

Furthermore, numerous specific details are set forth in order to provide a thorough understanding of the implementations described herein. However, it will be understood by those skilled in the relevant arts that the implementations described herein may be practiced without these specific details. In other instances, well-known methods, procedures and components have not been described in detail so as not to obscure the implementations described herein.

In this specification, elements may be described as “configured to” perform one or more functions or “configured for” such functions. In general, an element that is configured to perform or configured for performing a function is enabled to perform the function, or is suitable for performing the function, or is adapted to perform the function, or is operable to perform the function, or is otherwise capable of performing the function.

It is understood that for the purpose of this specification, language of “at least one of X, Y, and Z” and “one or more of X, Y and Z” may be construed as X only, Y only, Z only, or any combination of two or more items X, Y, and Z (e.g., XYZ, XY, YZ, ZZ, and the like). Similar logic may be applied for two or more items in any occurrence of “at least one . . . ” and “one or more . . . ” language.

Unless defined otherwise, all technical and scientific terms used herein have the same meaning as commonly understood by one of ordinary skill in the art to which this invention belongs.

Throughout the specification and claims, the following terms take the meanings explicitly associated herein, unless the context clearly dictates otherwise. The phrase “in one of the embodiments” or “in at least one of the various embodiments” as used herein does not necessarily refer to the same embodiment, though it may. Furthermore, the phrase “in another embodiment” or “in some embodiments” as used herein does not necessarily refer to a different embodiment, although it may. Thus, as described below, various embodiments may be readily combined, without departing from the scope or spirit of the innovations disclosed herein.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

The term “comprising” as used herein will be understood to mean that the list following is non-exhaustive and may or may not include any other additional suitable items, for example one or more further feature(s), component(s) and/or element(s) as appropriate.

Reverse engineering (RE) is now a common practice in the electronics industry with wide ranging applications, including quality control, the dissemination of concepts and techniques used in semiconductor chip manufacture, and intellectual property considerations with respect to assessing infringement and supporting patent licensing activities.

However, with ever-increasing integration levels of semiconductor circuits, RE has become increasingly specialised. For instance, many RE applications often require advanced microscopy systems operable to acquire thousands of images of integrated circuits (ICs) with sufficient resolution to visualise billions of micron and sub-micron features. The sheer number of elements that must be processed demands a level of automation that is challenging, particularly in view of the oft-required need of determining connectivity between circuit elements that are not necessarily logically placed within a circuit layer, but rather disposed to optimise use of space.

Various approaches for automatically analysing ICs have been proposed. One method is described in U.S. Pat. No. 5,694,481 entitled “Automated Design Analysis System for Generating Circuit Schematics from High Magnification Images of an Integrated Circuit” and issued to Lam, et al. on Dec. 2, 1997. This example, which illustrates an overview of the IC RE process in general, discloses a method for generating schematic diagrams of an IC using electron microscopy images. Due to the high resolution required to image circuit features, each layer of an IC layer is imaged by scanning many (tens to millions of) subregions independently, wherein such ‘tile’ images are then mosaicked to generate a more complete 2D representation of the IC. These 2D mosaics are then aligned in a third dimension to establish a database from which schematics of the IC layout are generated.

With respect to the actual extraction of circuit features, however, such automatic processes may be challenged by many factors, not the least of which relate to the nature of the imaging techniques required to visualise such small components. For instance, the relatively widely used processes of scanning electron microscopy (SEM), transmission electron microscopy (TEM), scanning capacitance microscopy (SCM), scanning transmission electron microscopy (STEM), or the like, often produce images with an undesirable amount of noise and/or distortion. While these challenges are manageable for some applications when a circuit layout is already known (e.g. IC layout assessment for compliance with design rules), it is much more challenging to extract circuit features from imperfect data in an automated fashion when there is no available information about the intended circuit design.

Various extraction approaches have been proposed. For instance, the automated extraction of IC information has been explored in United States Patent Application No. 5,086,477 entitled “Automated System for Extracting Design and Layout Information from an Integrated Circuit”, issued Feb. 4, 1994 to Yu and Berglund, which discloses the identification of circuit components based on a comparison of circuit features with feature templates, or feature template libraries. However, such libraries of reference structures are incrementally built for each unique component and/or configuration. In view of how the components of even a single transistor (i.e. a source, gate, and drain), or a logic gate (e.g. OR, NAND, XNOR, or the like) may have a wide range of configurations and/or shapes for performing the same function, this approach is practically very challenging, often resulting in template matching systems requiring a significant amount of operator intervention, and which are computationally very expensive, and limited to specific component configurations (i.e. lack robustness).

For instance, a NAND gate may comprise a designated number and connectivity transistors in series and in parallel. However, the specific configuration and placement of transistor features (e.g. the size, shape, and/or relative orientation of a source, gate, and drain for a transistor), and the configuration of the different transistors of the NAND gate, may vary even between even adjacent gates in an IC layer. An operator would therefore need to identify each transistor geometry present in each gate for inclusion into a template library, wherein automatic extraction of subsequent transistor components may only be successful only if a previously noted geometry is repeated.

Despite these deficiencies, this approach remains common in IC RE practice. For example, U.S. Pat. No. 10,386,409 entitled ‘Non-Destructive Determination of Components of Integrated Circuits’ and issued Aug. 20, 2019 to Gignac, et al., and U.S. Pat. No. 10,515,183 entitled ‘Integrated Circuit Identification’ and issued Dec. 24, 2019 to Shehata, et al., both disclose the identification of circuit elements based on pattern matching processes.

More generally, it may be important for various applications to extract specific types of features from images of ICs. For instance, many RE or development applications may rely on the identification of wires, vias, diffusion areas, polysilicon features, or the like, from SEM images. While a common approach to this end is image segmentation, automatic extraction of features is challenged by, among other aspects, low segmentation accuracy arising from noisy images, contamination, and intensity variation between circuit images. Particularly challenging for automating feature using segmentation is the fact that, while noise and/or general brightness of given features are relatively consistent within an image, these parameters can vary significantly image-to-image. Accordingly, extracting features from an SEM image using segmentation approaches, which may be broadly understood as assigning pixel values based on a corresponding brightness of a pixel in an original image, are highly prone to error when the brightness of a given feature differs between images. Resultant errors may be very time consuming to correct by an operator.

Existing circuit segmentation processes are also highly dependent on user-tuned parameters to achieve reasonable results. For example, Wilson, et al. (Ronald Wilson, Navid Asadizanjani, Domenic Forte, and Damon L. Woodard, ‘Histogram-based Auto Segmentation: A Novel Approach to Segmenting Integrated Circuit Structures from SEM Images’, arXiv: 2004.13874, 2020) discloses an intensity histogram-based method to automatically segment integrated circuits. However, there is no quantitative analysis of performance in this report with respect to different integrated circuit images having significant intensity variation. Moreover, while focus is placed on wire segmentation, there is lacking adequate extraction of information with respect to vias, such as accurate via location data, which is an important aspect of many semiconductor analysis applications. Similarly, Trindade, et al. (Bruno Machado Trindade, Eranga Ukwatta, Mike Spence, and Chris Pawlowicz, ‘Segmentation of Integrated Circuit Layouts from Scanning Electron Microscopy Images’, 2018 IEEE Canadian Conference on Electrical Computer Engineering (CCECE), 1-4, DOI: 10.1109/CCECE.2018.8447878, 2018) explores the impacts of different pre-processing filters on scanning electron microscopy (SEM) images, and proposes a learning-free process for integrated circuit segmentation. However, again, the effectiveness of the proposed approach relies on a separation threshold, which may be challenging if not impossible to generically establish across images with a large variation in intensity or in circuit configurations. Moreover, depending on various aspects of an image (e.g. quality, noise, contrast, or the like), such a threshold may not even exist.

A possible approach to automating the identification of IC features is through the employ of a machine learning (ML) architecture for recognising specific features or feature types. However, such platforms remain challenged by issues relating to, for instance, image noise, intensity variations between images, and/or contamination. Moreover, unlike with image recognition processes applied to conventional photographs, IC images may often be discontinuous, histograms may often be multi-modal, and the relative location of modes within histograms may change between image captures. Mode distributions for components (e.g. wires, vias, diffusion areas, or the like) may overlap. For some applications, the size and distribution of features may present a further challenge to analysis. For example, vias tend to be numerous, small, and sparsely distributed, similar to contamination-based noise. Further, image edges may be problematic, wherein, for example, some wires may be difficult to distinguish from vias when they are ‘cut’ between adjacent images (i.e. edge cutting). This challenge may be exacerbated by the fact that, due to memory and/or processing constraints, machine learning processes may require cutting images into smaller sub-images.

Generally, ML processes known in the art still require user tuning of user-tuned parameters or hyperparameters. With respect to IC component recognition, this may relate to a user being required to hand-tune parameters for, for instance, every grid or image set, and/or those having differing intensities and/or component distributions. Such platforms or models are thus not generic, requiring user intervention to achieve acceptable results across diverse images or image sets. Moreover, ML systems are not one-size-fits-all, wherein, for instance, different outputs may be preferred for different object types. For example, many applications may require accurate information with respect to via location(s) within an IC, while for wires, continuity and/or connectivity may be a primary focus. This may be different from conventional machine learning approaches, which may often have a particular output goal (e.g. pixel-by-pixel segmentation), and/or may be evaluated using a consistent metric (e.g. recall, precision, or confidence score). For example, Lin et al. (Lin, et al., ‘Deep Learning-Based Image Analysis Framework for Hardware Assurance of Digital Integrated Circuits’, 2020 IEEE International Symposium on the Physical and Failure Analysis of Integrated DOI: Circuits (IPFA), pp. 1-6, 10.1109/IPFA49335.2020.9261081, 2020) proposes a deep learning-based approach to recognising electrical components images. However, the proposed process relates to a fully convolutional network that is used to perform segmentation of target features within SEM images of ICs. That is, both vias and metal wire features are recognised using the same segmentation process executed using the same machine learning architecture. However, different image features may be more suitably recognised using different processes and/or architectures. Moreover, the machine learning models of Lin et al., despite being applied to images with less than noise than is characteristic of those acquired in industrial applications, are not reusable between images of different ICs, or even different IC layers. That is, the systems and processes of Lin et al. require retraining for each new image to be processed, which is not practical for industrial applications.

In, for instance, IC reverse engineering applications, it may be desirable for an output (e.g. a segmentation output for wires) to have both correct electrical connectivity between wires, but also maintain a desired level of aesthetic quality. That is, it may be preferred to output a segmentation result that has correct electrical connectivity, while approximating how a human would segment an image. However, some aspects of conventional segmentation may be less critical. For example, a small hole in a wire, or a rough edge thereof, may be less critical for an application than continuity (i.e. electrical conductivity). On the other hand, via placement within an IC with respect to wires and the like may be more important than a via shape. Accordingly, evaluation of the quality of ML outputs with respect to these different objects may rely on different aspects. Further, it may be preferred to recognise different objects or types in accordance with fundamentally different recognition processes. For example, with respect to circuit feature recognition from SEM images, segmentation may provide an effective means of recognising wires and/or diffusion areas. However, segmentation may be less effective for via recognition than a detection process, depending on the application at hand.

The above notwithstanding, segmentation remains a promising avenue for extracting via information from SEM images of an IC. However, a need exists, with respect to the extraction various circuit features, including, without limitation, wires and vias, for a system and method that overcomes various drawbacks associated with SEM imaging of ICs, such as random contaminations on exposed surfaces, improper and/or variable exposure settings during image acquisition, improper layer removal during RE processes, and the like, which often lead to unexpected and/or excessive errors in segmentation results. As incorrectly interpreting connectivity of components can be severely detrimental for many applications, a human is often required to identify and/or correct errors. However, as the number of images that are processed for various tasks can range from thousands to millions, this task can be highly challenging and time consuming, and present a bottleneck for large scale industrial applications. Accordingly a need exists to, among other aspects, identify errors arising from automated processing of images. At the same time, this may relate to, for example, a need to identify when there is little likelihood of an error arising from an automated extraction process, thus saving time the time and cost associated with human verification of outputs and/or images where there is little or no need.

At least in part to this end, the systems and methods described herein provide, in accordance with different embodiments, different examples of analysis methods and systems for detecting potential errors in digitally analysed images. While various exemplary embodiments described relate to the recognition of circuit features (e.g. wires, vias, diffusion areas, and the like) from integrated circuit images, it will be appreciated that such embodiments may additionally or alternatively be deployed to, for example, detect differences between image-like data sets generated from one form of an image, and another form of image corresponding to the same object, surface, or substrate from which the image-like data sets were obtained. For example, while some embodiments relate to the recognition of errors in wire and via features extracted from digital representations (e.g. digital SEM images or portions thereof) of ICs, other embodiments may relate to the recognition of errors arising from analysing different object types (people, structures, vehicles, or the like) from other forms of media (e.g. photographs, videos, topographical maps, radar images, or the like). Additionally, or alternatively, various embodiments may relate to, for example, the detection of ‘errors’ as differences between images of, for example, a terrain or map-like data structure. For example, images of the same geographical region acquired at different times, or digital representations or derivatives thereof (e.g. segmented copies of the original images acquired at different times) may be analysed in accordance with the systems and methods herein described to, for example, identify potential areas where terrain has changed, such as the addition or removal of forested areas, roads, buildings, or the like.

Generally, embodiments herein described relate to the recognition of object types from images using one or more machine learning recognition models, architectures, systems, or processes. In some embodiments, this may relate to the selection or use of respective machine learning architectures and/or models for respective object types (e.g. respective architectures for wires and vias). It will be appreciated that, in embodiments where a plurality of machine learning architectures is employed, respective machine learning processes or models may be employed from a common computing architecture (either sequentially or in parallel), or from a plurality of distinct architectures or networks. For example, a networked computational system may access different remote ML architectures via a network to perform respective ML recognition processes in accordance with various ML frameworks, or combinations thereof, in accordance with some embodiments. Moreover, it will be appreciated that the systems and methods herein described may be extended to any number of object types. For instance, a plurality of object types (e.g. 2, 3, 5, 10, or N object types) may be recognised using any suitable combination of ML architectures. For instance, one embodiment relates to the recognition of five object types from images using three different machine learning architectures. One or more of these machine learning architectures may be employed in parallel for independent and simultaneous processing, although other embodiments relate to the independent sequential processing of images or digital representation thereof.

It will therefore be appreciated that various aspects of machine learning architectures may be employed within the context of various embodiments. For example, the systems and methods herein described may comprise and/or have access to various digital data processors, digital storage media, interfaces (e.g. programming interfaces, network interfaces, or the like), computational resources, servers, networks, machine-executable code, or the like, to access and/or communicate with one or more machine learning networks, and/or models or digital code/instructions thereof. In accordance with some aspects, embodiments of the systems or methods may themselves comprise the machine learning architecture(s), or portions thereof.

Moreover, it will be appreciated that machine learning architectures or networks, as described herein, may relate to architectures or networks known in the art, or portions thereof, non-limiting examples of which may include ResNet (e.g. ResNet18 or other), HRNet (e.g. HRNet-3, HRNet-4, HRnet-5, or the like), pix2pix, or YOLO, although various other networks (e.g. neural networks, convolutional neural networks, or the like) known or yet to be known in the art may be employed and/or accessed. Further, various embodiments relate to the combination of various partial or complete ML networks. For example, one embodiment relates to the combination of aspects of ResNet, Faster R CNN, and/or HRNet to recognise an object type from images. In accordance with yet other embodiments, and depending on, for instance, the object type to be recognised and/or the needs of a particular application, various layers and/or depths of ML networks may be employed to process images for recognising objects therein. It will further be appreciated that, as referred to herein, a machine learning architecture may relate to any one or more ML models, processes, code, hardware, firmware, or the like, as required by the particular embodiment or application at hand (e.g. object detection, segmentation, or the like).

For instance, a non-limiting example of a machine learning architecture may comprise an HRNet-based machine learning framework (e.g. HRNet-3, HRNet-4, or the like). An HRNet-based framework and/or architecture may be used to train and/or develop a first machine learning model for a particular application (e.g. wire segmentation), wherein the model is reusable on a plurality of images (i.e. is sufficiently robust to segment wires from a plurality of images, IC layers, images representative of different ICs, or the like). In accordance with some embodiments, a machine learning architecture may, depending on the context, and as described herein, comprise a first machine learning model (or a combination of models) that may be employed in accordance with the corresponding machine learning framework (e.g. HRNet) to recognise instances of an object type in a plurality of images.

In accordance with some embodiments, a machine learning architecture may, additionally or alternatively, comprise a combination of machine learning frameworks (e.g. HRNet and ResNet). That is, the term ‘machine learning architecture’, as referred to herein, may relate not only to a single machine learning framework dedicated to a designated task, but may additionally or alternatively relate to a plurality of frameworks employed in combination to recognise instances of a designated object type. Moreover, a machine learning architecture, or the combination of machine learning frameworks thereof, may produce different forms of output (e.g. datasets related to object detection versus datasets related to object segmentation) depending on the application at hand.

Moreover, it will be appreciated that while various embodiments herein described may relate to the employ of one or more machine learning architectures configured as a ‘classifier’, wherein output relates to a ‘classification’, or to ‘image translation’, other architectures and/or outputs are expressly hereby considered, such as ‘object detection’ networks, ‘object recognition’ networks, or the like, to name a few non-limiting examples. The configuration of machine learning architectures for such embodiments, in view of the examples provided herein with respect to classification and translation, will be appreciated by the skilled artisan.

Generally, and as noted above, various embodiments relate to mitigating challenges associated with automatically identifying potential errors in segmented images. While the following description relates to the detection of potential errors with respect to two exemplary object types (e.g. wires and vias from segmented SEM images), errors with respect to other object types, which may or may not relate to segmented SEM images, are hereby considered.

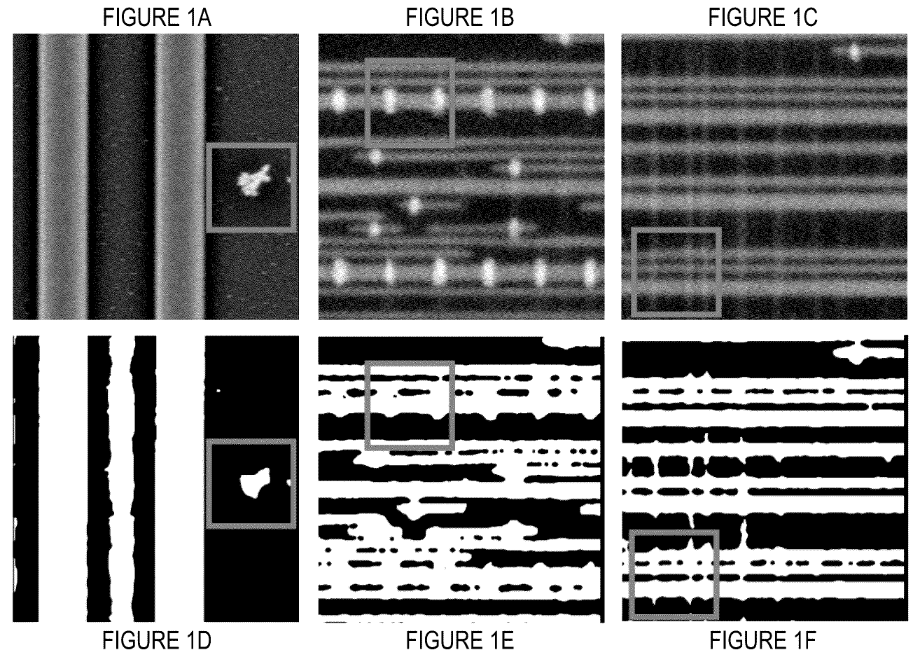

With respect to the segmentation of wires and vias from SEM images, conventional processes and systems are challenged by, for example, image quality, which may be affected by, to name a few non-limiting examples, imperfect or variable exposure during image acquisition, imperfection or variability in processes employed to remove layers from an IC, and/or contamination on surfaces being imaged. Such non-limiting examples of challenges with respect to obtaining accurate segmentation results are illustrated in FIGS. 1A to 1F. In these examples, FIGS. 1A to 1C show SEM images of various regions of an IC layer, while FIGS. 1D to 1F show corresponding wire segmentations results for, respectively, FIGS. 1A to 1C, in accordance with some embodiments.

In these examples, square boxes serve as a guide to the eye for highlighting various aspects that may present challenges with respect to segmentation to extract circuit features and/or connectivity thereof. In FIGS. 1A and 1D, surface contamination (e.g. random or pseudo-random contamination) appears as a bright feature in the SEM image of FIG. 1A, and accordingly appears in the corresponding segmentation result of FIG. 1D, in this case having been segmented as if it was a wire feature. This result, in accordance with some embodiments, corresponds with an error in the segmentation result of FIG. 1D.

Similarly, FIG. 1E shows the segmentation result from the SEM image of FIG. 1B. In this case, improper exposure during SEM image acquisition in FIG. 1B provided the segmentation result of FIG. 1E having various errors in connectivity between wires in the region indicated by the corresponding squares overlaid on the images.

Finally, FIG. 1F shows the segmentation result for the SEM image of FIG. 1C, wherein the region indicated by the corresponding squares highlights improper wire connectivity arising from improper layer removal prior to SEM imaging. In this case, vertical streaks are visible artefacts which appears, in segmented images, to connect wires that are not, in reality, connected in the areas shown.

Among other aspects, various embodiments relate to improving the automation of feature extraction from images such as those shown in FIGS. 1A to 1C through the automation of potential error identification in images segmented therefrom, such as those shown, for illustrative purposes, only, in FIGS. 1D to 1F.

For example, various embodiments relate to a method or system for automatically detecting potential errors in segmented images. While the following description relates to a method for such ends, it will be appreciated that various aspects may similarly be incorporated for a system employing one or more aspects of the method, as appropriate. Moreover, it will be appreciated that while the following discussion generally relates to the processing of images acquired by a scanning electron microscope (SEM), other forms of images and/or data types may be similarly processed, in accordance with different embodiments. For example, similar methods or systems may relate to the processing of optical images, or optical microscopy images. Similarly, various embodiments relate non-optical microscopy techniques, a non-limiting example of which may comprise electron microscopy, of which SEM is provided in turn as a non-limiting example. In accordance with various embodiments, it will be appreciated that a sensor used for acquiring such datasets may be further considered as, for example, an element of a system as herein described, although various embodiments do not require that such a sensor be a component of a system as herein described. For example, various embodiments relate to systems and methods more generally directed to various aspects of processing data ultimately acquired from such sensors.

In some embodiments, a method for detecting potential errors in segmented images may be executable by one or more digital data processors. Such a method may generally comprise receiving as input at least one segmented image, wherein the at least one segmented image each comprise a respective array of segmented pixel values, each calculated in respect of a corresponding portion of an input image. For example, and for illustrative purposes, only, an image may comprise an SEM image of an IC circuit layer, non-limiting examples of which are shown in FIGS. 1A to 1C. However, it will be appreciated that such images may comprise, for example, aerial imagery of terrain, including roads, forested regions, hills, or the like.

With reference to the exemplary images of FIGS. 1A to 1C, respective arrays of pixel values calculated in respect thereof may correspond with respective segmented images, non-limiting examples are shown in FIGS. 1D to 1F. As segmented images generally comprise a digital representation of original images (e.g. SEM images in FIGS. 1A to 1C), they may comprise, in some embodiments, arrays of pixel values generally corresponding with respective regions of an original image. That is, in some embodiments, a given pixel of an original image may be assigned a corresponding value in a segmented image based, for example, on a brightness or colour associated with the pixel in the original image. However, it will be appreciated that, in some embodiments, a pixel value for a segmented image (e.g. a pixel in array of segmented pixel values) may generally correspond with any number of pixels, or parameter associated with one or more regions, of a base or original image, and may thus generally relate to a calculated value that is not necessarily representative of a single corresponding pixel in the original image (although it may, in some embodiments). For example, a segmented image may comprise one that is of lower resolution than an image from which it derived. Each pixel of the segmented image or array corresponding thereto may thus relate to an average, or other parameter, of pixel values (or indeed a segmentation value associated therewith) for a corresponding region of the original or base image.

Further, it will be appreciated that, in such contexts, and indeed throughout the disclosure, the term ‘pixel’ may be used for clarity, but may, in addition or as an alternative to corresponding with the notion of a single unit of a 2D image, refer to a voxel, or more generally to a corresponding term inherently relating to other dimensionalities. For instance, as used herein, the term ‘pixel’ is not to be understood as relating only to a unit of a two-dimensional image, but may rather refer, in some non-limiting embodiments, to any equivalent or similar term for a one-dimensional, three-dimensional, or higher-dimensional (e.g. n-dimensional) image. Similarly, the term ‘image’, as used herein, will be appreciated as not only relating to a two-dimensional image, as is shown for clarity in the Figures herein provided, but may refer to one-dimensional, three-dimensional, or n-dimensional variants thereof. For example, various embodiments herein described may be equally or similarly applied to MRI ‘images’ comprising, on a ‘pixel-by-pixel’ basis, more information than is conventionally or simply understandable by 2D representations thereof.

In accordance with various embodiments, the systems and methods herein described may provide for identifying one or more error types associated segmented images. For example, some methods herein described provide for identifying both first and second error types corresponding with, for example, errors related to both wires and vias as estimated from segmented images. Depending on, for instance, the particular object types or the nature of images being processed, and as noted above, one or more machine learning architectures and corresponding models may be applied to identify error types.

For example, and in accordance with some embodiments, a method may relate to identifying a first error type by digitally translating, using a digital image-to-image translator, at least one segmented image to a reconstructed image. Upon execution of a comparison of a reconstructed image with the corresponding input image(s) (e.g. an original image, or a base image from which the segmented image was derived), one or more regions of disparity between the original and the reconstructed image may be digitally identified. This may be performed, for example, in accordance with a designated comparison parameter, as further described below.

Meanwhile, as performed either simultaneously using a respective machine learning architecture, before or after execution of the identification of the first error type, or the like, a method may comprise identifying a second error type. This may relate to, for example, calculating an extension array in at least one dimension of a respective array of segmented pixel values corresponding to the input or original image(s). This may be performed, in accordance with some embodiments, on one or more dimensions of the input image, depending on the application at hand. In some embodiments, and based at least in part on the given segmented image and corresponding extension array, such a method may further comprise identifying, via a digital image classifier having access to a trained error detection model, a potential error in the given segmented image(s).

Generally, such methods may further relate to, upon positively identifying one or more of a region of disparity (e.g. from the identification of the first error type) or the potential error (e.g. in the identification of the second error type), providing a corresponding error signal in association with a corresponding segmented image(s) from which errors were identified. Accordingly, a user of such a method or a system employing the same may be provided with, for example, an indication of which (if any) segmented images may have a (high) probability of error associated therewith, thereby significantly reducing the time and cost associated with inspected segmentation outputs, which may otherwise relate to inspected thousands to millions of images. Similarly, this may relate to, in cases where there is little to no error in segmentation results from a prior segmentation process on the image(s) in question, eliminating the need for manual inspection of one or more images, which may correspond with preventing the user from unnecessarily inspecting thousands to millions of images.

While the foregoing example generally relates to the identification of a plurality of error types based on the analysis or respectively segmented images for each of two error types, it will be appreciated that various embodiments may additionally or alternatively relate to the identification of any one error type, without necessarily requiring the identification of a second error type from the same image(s). Accordingly, the following description relates to, for illustrative purposes, only, the identification of two different error types, which may be applied independently from one another, in accordance with some embodiments.

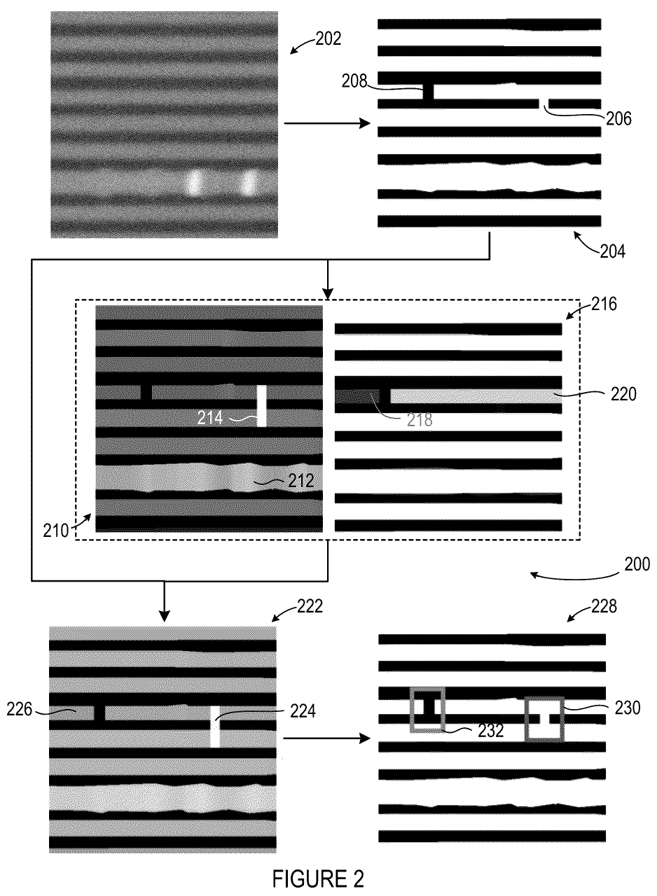

For example, and in accordance with some embodiments, FIG. 2 schematically illustrates an exemplary non-limiting method 200 for automatically detecting potential errors of a given error type in segmented images. As noted above, this non-limiting method, or a corresponding system, may be executable by one or more digital data processors. For illustrative purposes, this example relates to the identification of potential errors in segmentation output of an SEM image with respect to identifying wires therefrom, although it will be appreciated that other object, image, and/or extraction types may be similarly applied, in accordance with other embodiments.

In the exemplary embodiment of FIG. 2, the process 200 relates to the analysis of various derivatives of an SEM image 202 of a region of an IC. While, generally, a process as herein described does not necessarily require the execution of obtaining such an image, it will be appreciated that some embodiments do indeed relate to the acquisition of the image 202, and/or subsequent processing thereof. It will further be appreciated that, generally, an SEM image 202 may comprise, for example, the entirety of a layer of an IC. However, and in accordance some embodiments, an SEM image 202, or more generally an input image 202, may comprise a portion of an SEM image (e.g. an image patch or tile) that is defined based on, for example, a region of a corresponding IC layer or other substrate that may be realistically or practically imaged using an SEM or other imaging source for a given imaging configuration.

For instance, in practice, only a limited region of an IC layer may be imaged at a time. Different regions may be imaged, for example, sequentially, wherein images of different regions are subsequently patched together in a ‘mosaic’, wherein spatial relationships may be more or less preserved in the mosaic depending on the accuracy of a mosaicking process, and/or the quality of the images corresponding to different regions of the IC layer or substrate. Accordingly, in some embodiments, an SEM image, such as the image 202 of FIG. 2, may correspond to a given imaging region of the IC layer. In other embodiments, the image 202 may correspond with a sub-region of a larger image of an IC layer, for instance one that has already been mosaicked. In the non-limiting example of FIG. 2, the image 202 corresponds with the latter example, wherein the image 202 has been defined from a larger image, and wherein the area of the image 202 is defined based on the amount of memory and other computational resources for executing subsequent steps of the process 200. However, it will be appreciated that other embodiments may relate to an otherwise defined region(s) of a substrate or other object being imaged (e.g. sub-regions of aerial imagery acquired from a given imaging position with respect to Earth).

In accordance with some embodiments, whether or not a process comprises acquiring the image 202, the process 200 relates to receiving as input a segmented image 204 derived from the image 202. For example, some embodiments relate to executing a segmentation process on the image 202, the output 204 of which is received for subsequent processing. Other embodiments, including the non-limiting example of FIG. 2, relate to the receipt as input of such a segmented image 204.

In this example, the segmented image 204 comprises an array of segmented pixel values 204 each calculated in respect of a corresponding portion of an image. As noted above, such an array of pixels 204 may correspond one-to-one with pixels of the SEM image 202, or may correspond or more generally relate to pixel values representative of (e.g. an average, a median value, or another metric of) a corresponding region of the original image 202.

In this example, and in accordance with various embodiments, the segmented image 204 comprises an array pixels, wherein pixels are assigned a given value based on whether they are interpreted as wires or background during segmentation based at least in part on intensity values of the corresponding pixels of the SEM image 202. In this case, pixels identified as wires as are shown as bright (white) pixels in the segmented image 204, while pixels identified as background are dark (black). However, it will be appreciated that pixels may be assigned any particular or number or particular values (e.g. a wire pixel value w, a background pixel value b), depending on the particular implementation at hand. Moreover, in embodiments related to the segmentation of, for example, more than one object type in addition to background, multiple segmentation values may be assigned (e.g. values of w, v, and b for wires, vias, and background, respectively).

In this case, the segmented image 204 contains examples of segmentation errors, wherein, for any number of reasons, the extraction of wire features from the SEM image 202 produced improper connectivity (e.g. connections or lack thereof not existing in the original substrate from which the SEM image 202 was acquired). For example, the segmentation image 204 comprises a short 206 between wires that are not, to the human eye, connected in the SEM image 202. On the other hand, the segmentation image 204 shows a disconnection 208 in a wire that is continuous based on human inspection of the SEM image 202.

In accordance with various embodiments, a segmented image, such as the segmented image 204, may be subsequently processed in the method 200 to synthesise further data representative of the segmented image, and accordingly representative of the original image 202, to improve upon error detection in segmentation, and accordingly to improve upon the automated processing of images. For example, and in accordance with various embodiments, the method 200 of FIG. 2 further illustrates how the segmented image 204 may be used to synthesise data to improve subsequent processing.

In this non-limiting example, the segmented pixel values 204, and accordingly the segmented image 204, is processed to generate respective extension arrays 210 and 216 comprising, for each given pixel of the segmentation array 204, a corresponding extension value. In this case, two extension arrays 210 and 216 are calculated for each pixel of the segmentation image 204, wherein the first array 210 corresponds with the vertical extension of each pixel value of the segmentation array 204, while the second array 216 corresponds with the horizontal extension of each pixel value of the segmentation array 204. However, in accordance with other embodiments, a single extension array (e.g. one of horizonal, vertical, or another axis) may be calculated for each pixel, or for each group of a plurality of groups of pixels defined from the segmentation array 204. Similarly, for segmentation images relating to a dimensionality of greater than 2, more than two extension arrays may be calculated for each n-dimensional pixel. In yet further embodiments, any number of extension array may be calculated for each pixel or group thereof, without necessarily exhausting the inherent dimensionality of each n-dimensional pixel.

In accordance with various embodiments, an extension array 210 and/or 216 may be representative of an extension of a given or designated segmentation value in a corresponding dimension of the array of segmented pixel values 204. That is, for a given pixel having a given segmentation value (e.g. a given pixel has a segmentation value w corresponding with a wire pixel interpreted during segmentation of the SEM image 202), an extension array value may correspond with the number consecutive or contiguous pixels, in a given dimension (e.g. horizontal, vertical, or along another axis), that share the segmentation value.

For example, if pixel i is assigned as a wire pixel having a segmentation value of w, and, in the horizontal direction of the segmentation array 204, pixel i has 5 consecutive neighbours in the negative direction (e.g. to the left of pixel i) sharing the segmentation value w, and 14 consecutive neighbours in the positive direction (e.g. to the right of pixel i) sharing the segmentation value w, then the pixel in a horizontal extension array corresponding to the pixel i may be assigned a value of 20 (i.e. 1 pixel for pixel i+5 pixels for the wire values to the left of pixel i+14 pixels for the pixels having wire values to the right of pixel i=a value of 20 for the pixel i in the horizontal extension array).

While, for exemplary purposes, only, an extension array as herein described relates to contiguous pixels that share values in a segmentation array 204 that share a common value (i.e. the number of consecutive pixels sharing the same value before being interrupted by, for example, a pixel labelled as a ‘background’ pixel), it will be appreciated that other embodiments may relate to other functions applied in determining an extension array pixel value. For example, various smoothing functions may be applied to a segmentation array 204 and/or extension array 210 or 216 to, for instance, reduce sensitivity of extension array values to noise, without departing from the general scope and/or nature of the disclosure.

With continued reference to FIG. 2, and in accordance with some embodiments, respective extension arrays may be computed for pixel values of a segmentation array 204 for any number of dimensions. For example, the extension array 216 relates to a ‘horizontal’ extension array 216 of pixels of the segmented image 204, as described above, while the extension array 210 relates to a ‘vertical’ extension array 210 of the pixels of the segmented image 204. However, in accordance with other embodiments, only one extension array may be computed for pixel values of a segmented image 204 (e.g. a horizontal array 216), while other embodiments may relate to the computation of any number, up to n, of an n-dimensional array of pixel values for an image 202 or 204.

In accordance with various embodiments, extension arrays (e.g. extension arrays 210 and 216) may provide data that is synthesised from an image (e.g. SEM image 202 and/or segmentation image 204) that provides useful information for downstream processing. For example, even to the human eye, the vertical extension array 210 comprises an array of extension values that accentuate, via the bright feature 214, the short 206 of the segmentation array 204. That is, as a result of the relatively large number of consecutive ‘vertically aligned’ wire pixel values in the interpreted short 206 in the segmentation array 204, the vertical extension array 210, which counts consecutive ‘wire’ pixels in the segmentation array 204 for each pixel thereof, shows relatively large values in the region 214. Similarly, because the segmentation image 204 interpreted a wire 212 of varying vertical width, the extension array 210 shows varying vertical extension values (represented in FIG. 2 as varying pixel brightness intensities) for the wire 212 in the extension array 210.

Similarly, the exemplary ‘horizontal’ extension array 216 shows extension array values as a brightness intensity for each pixel of the segmentation image 204 based at least in part on, for each pixel of the segmentation image 204, a corresponding number of ‘wire’ pixels contiguous therewith in the horizontal direction. In this case, as the segmentation image 204 is interpreted as having a disconnection 208 in an otherwise continuous horizontal wire (e.g. assigned values in the region 208 as ‘background’), the region 218 in the horizontal extension array 216 comprises relatively ‘small’ extension values (shows as a lack of brightness intensity in FIG. 2). That is, because the horizontal extension of any pixel corresponding with a wire value in the region 218 is less than, for example, that of a pixel corresponding to a wire that extends, horizontally, completely across the segmented image 204, the horizontal extension value of a pixel in region 218 is relatively low, and thus appears (for illustrative purposes) as relative dark in FIG. 2. Similarly, while any pixel in the region 220 of the horizontal extension array 216 is relatively brighter (i.e. has a higher extension value) than a pixel in the region 218, because the corresponding wire ‘appears’ longer in the corresponding segmentation image 204, it is nevertheless darker (i.e. has a lower extension value) than any given pixel in corresponding with a wire that extends completely, in the horizontal direction, across the segmentation image 204.

While the foregoing description makes reference to array values and/or sizes as if, for example, values were ultimately calculated for the SEM image area illustrated by the image patch 202 of FIG. 2, it will be appreciated that, in accordance with various embodiments, any one or more of an input image 202, a segmentation image or array 204, or an extension array 210 or 216 may be representative of a corresponding array or image that is larger than that depicted in FIG. 2, or is larger than that employed in any previous or subsequent processing step(s).

For example, and as described above, constraints in processing resources, such as a digital memory and/or machine learning processing ability, may necessitate or suggest that images, arrays, or data representative thereof be input in accordance with a designated size (e.g. memory allotment, area, or the like). Accordingly, while images or arrays presented in FIG. 2 may be illustrated, for clarity, in accordance with a designated or fixed size for a given processing step, it will be appreciated that any one or more of such images or datasets may comprise, or be representative of, arrays or images of a different size (e.g. a larger area, dimension, extent, or the like).

For example, while the SEM image 202 is depicted as an image tile 202 having a designated size that is correspondingly represented by each of the corresponding segmentation array 204 and extension arrays 210 and 216, the embodiment of FIG. 2 relates to each of the arrays 202, 204, 210, and 216 corresponding, ultimately, with images and datasets that are larger than those represented in FIG. 2. For instance, various embodiments relate to, prior to the process 200 of FIG. 2, establishing a mosaic image of thousands of SEM images 202, which is accordingly thousands of times larger in area that the depicted image 202. Accordingly, the corresponding segmented image 204 may correspond with a segmented image that is thousands of times larger than the segmented array 204 of FIG. 2. Similarly, extension values of extension arrays 210 and 216 may correspond to, for each pixel thereof, extension values representative of extension of a given pixel value in the larger (e.g. thousands of times larger) segmented image corresponding ultimately to the entire mosaic of SEM images, or a designated region thereof that does not necessarily correspond to the area represented in FIG. 2.

That is, and in accordance with various embodiments, an image (e.g. SEM image 202) may comprise an image that is too large to process, for instance by a machine learning architecture. However, various embodiments relate to preserving image data or properties beyond a region or area that may be processed by a computing resource in any given process step. Accordingly, while a segmentation image (e.g. segmentation array 204), as well as an extension array computed therefrom, may be subsequently processed in accordance with a defined smaller area or portion, data contained therein (e.g. extension values for a sub-region of a larger segmentation array) may be preserved upon definition of sub-arrays or image tile assignment. For example, while a segmented image and corresponding extension array(s) may be defined as limited to a width of 256 pixels for processing, an extension array, which defines, for example, a number of consecutive pixels in a given dimension that share a segmentation value, may comprise values exceeding 256, as the extension value may correspond to an extension of a given pixel value in a segmentation image that is much larger than that considered or transmitted as input for one or more subsequent processing steps. Accordingly, various embodiments relate to a means of providing various processing steps with information encoding properties that extend beyond that of any particular image or array subset than is currently being examined.

For example, and in accordance with some embodiments, an extension array may comprise values representative of an extension value, for any given segmentation pixel value of a segmented image 204, that represents the length or width of a feature comprising continuous values as extracted from a mosaicked SEM image that is 10 000 times wider than that depicted in FIG. 2, or otherwise defined herein for exemplary purposes. However, and in accordance with other embodiments, an extension value may correspond with a designated threshold or other form of function. For example, an extension value may be capped, for instance at a maximum extension value, in accordance with any one or more designated parameters. For example, while an extension array as shown in FIG. 2 may correspond with a width of 256 pixels, and be defined from a segmented image that is 2560 pixels in width, a maximum extension value may be defined as, for example 500 pixels in width, even if the wire corresponding thereto extended the entire width (i.e. 2560 pixels) in the segmented image.

Generally, and in accordance with various embodiments, an extension value, as described herein, may be computed, calculated, or assigned based on the corresponding object type for which it was defined. That is, while some embodiments relate to calculating an extension value for every pixel of segmented image, other embodiments, including that of FIG. 2, relate to computing an extension value (and accordingly, an extension array in one or more designated dimensions) only for pixels having a designated segmentation value(s). For example, the extension arrays 210 and 216 of FIG. 2 relate to calculating extension values in, respectively, vertical and horizontal dimension, only for pixels which are assigned as a wire (e.g. having a segmentation value w) in the segmented image 204. That is, values assigned as ‘background’ in the segmented image 204, ultimately from the SEM image 202, are not considered in the calculation of extension values. Accordingly, only ‘wire’ extension values are reported in the extension arrays 210 and 216, while the ‘background’ pixels are present, for spatial reference, but not subsequently processed to define extension values. However, it will be appreciated that other embodiments may equally consider, for example, background values in the computation of extension arrays. Similarly, in segmented images comprising more than two segmentation values (e.g. features in addition to background and wire segmentation values, such as vias), pixels related any number of such segmentation values may be considered for the computation of extension arrays, in accordance with various embodiments.

Moreover, it will be appreciated that, in accordance with various embodiments, such data representations may be normalised or otherwise processed for subsequent analysis. For example, and without limitation, extension value may comprise a normalised extension value representative of the extension of a designated segmentation value, normalised by a maximum extension value in a given respective extension array. For example, an extension value may be normalised (e.g. divided) by a maximum extension value in a given array corresponding thereto, whether or not the extension array considers, for example, wire values from a larger array, and/or contains values larger than a given dimension of the given extension array. This may be particularly beneficial in, for example, cases where different images (e.g. SEM image patch 202) are acquired in accordance with different exposure settings, or different images generally provide different brightness or colour values for otherwise similar features or object types.

With continued reference to FIG. 2, the process 200, having established one or more extension arrays corresponding to the array of segmented pixel values 204, may continue by providing a processing resource with data computed with respect to the input image 202. For example, some embodiments relate to the provision, to a machine learning architecture having access to a trained machine learning model, of one or more of the segmentation array 204 and one or more extension arrays 210 or 216.

Depending on, for example, the nature and/or architecture of the processing resource employed, one or more further processing steps may be employed prior to analysis. For example, if a machine learning platform and model are employed, the particular architecture of the machine learning platform, or again the nature of the training of an associated machine learning model, may be tailored or otherwise optimised or configured to accept certain types, formats, or configurations of data. Accordingly, a process step may relate to the conversion of image or array data to such a type, format, or configuration. While not required for many embodiments, FIG. 2 schematically depicts one exemplary data conversion.

In this non-limiting example, the segmented image 204, as well as respective extension arrays 210 and 216 corresponding thereto, are combined in an image stack 222. Such a stack 222 may be defined, for example, based on the particular configuration of a subsequent process resource. In this case the processing resource comprises a machine learning architecture having accessible thereto a trained error detection model, wherein the architecture is configured to receive as input a three-channel image (e.g. an RGB image), although it will be appreciated that other image types or data formats may be received as input, in accordance with other embodiments. Accordingly, various datasets from the process 200, in this example, are combined as an RGB image, although it will be appreciated by the skilled artisan that this represents one of many optional formats that may be optionally procured for processing. As shown in in the exemplary embodiment of FIG. 2, the stacked image 222 retains various features of the datasets extracted or computed from the original input image 202. For example, the stacked image retains data 224 related to the short 206 of the segmented image 204, while, for example, highlighting the relatively short nature of the region 226 of the wire ultimately arising from disconnection 208 in the segmented wire image 204.

Generally, and in accordance with various embodiments, a process or system as herein described may provide as an output an indication, as appropriate, of a potential error in a segmentation result (e.g. a potential error in a segmentation image 204 obtained from an input image 202). For example, in FIG. 2, a machine learning architecture having access to a trained error detection model outputs, from a stacked image 222 or other representation of an array of segmented pixel values 204 and each respective extension array 210 and 216, an error signal in association with the segmented image 228. That is, in this non-limiting example, an output corresponds with an indication (e.g. to a user), with respect to a segmented image 228 (in this case corresponding with the segmented image 204), that there may be associated therewith possible segmentation errors 230 and 232. In this case, as the exemplary machine learning architecture relates to a classification network, the potential errors are indicated as error regions/boxes 230 and 232. This example, in accordance with various embodiments, relates to the successful identification of potential errors in segmented image 228 or 204, as, as discussed above, the segmentation of image 202, shown as segmentation image 204, identified a wire short 206, shown by the error signal 230, and a disconnection 208, shown by the error signal 232, which do not appear to be, in reality, true features of the imaged IC.

It will be appreciated that, depending on the particular implementation at hand, various error signals may be provided, in accordance with different embodiments. For example, an output of such systems or methods may relate to a listing of segmentation inputs 204 that have associated therewith one or more potential errors, while other segmentation inputs 204 that do not have potential errors associated therewith may be otherwise ignored (e.g. not provided in association with a potential error). For example, a particular layer of an IC may have associated therewith thousands of tile images acquired using an SEM, with a corresponding number of segmented images extracted therefrom. In such cases, of the thousands of images, a user may be provided with a listing of only image tiles (and/or segmentation images 204 associated therewith) having potential errors, which may, for instance, be user-selectable, or presented sequentially, or the like, for human review.

While the embodiment of FIG. 2 illustrates the successful identification of potential errors in the segmented image 204, it will be appreciated that tremendous value may be manifested in the lack of identification of potential errors in processed images. For example, and as described above, in conventional approaches, a technician may be required to examine thousands of images in an attempt to identify possible errors in automated feature extraction results. In addition to the costs associated with such tasks, a human is liable to commit many errors in such a process due to, among other aspects, the repetitive nature of such a task, particularly in view of the relative success of many automated approaches which may yield hundreds of acceptable extraction results (which must often be verified by a human user) before segmentation results actually merit human intervention.

Moreover, while the embodiment of FIG. 2 illustrates the successful identification of potential errors in the segmented image 204, it will be appreciated that, for various applications, identifying the potential for an error in a segmentation result may similarly yield improvements in the automation of such tasks. For example, it may be, for some applications, relatively straightforward to identify errors in connectivity between components (e.g. some identified connectivities may be impossible or impractical, which may be readily automatically or digitally disregarded with sophisticated algorithms). However, by, for instance, reducing the burden on human users in identifying errors in automated extraction processes, such processes may be more readily improved, ultimately providing for better and/or more accurate systems and methods of extraction.

While the foregoing example is described with respect to the extraction of wires from an SEM image, it will be appreciated that the extraction of various other object types may be similarly understood within the general scope and nature of the disclosure. For example, similar concepts to those described above may be applied, in accordance with various embodiments, with respect to the extract of vias from SEM images, or indeed with respect to other features of other forms of images or derivatives thereof.

With respect to the exemplary embodiments of FIG. 2, various non-limiting configurational parameters will now be described for exemplary purposes, only. While such parameters may have been employed to, for example, produce the examples and/or results of FIG. 2, it will be appreciated that such parameters are non-limiting, and that variations of any one or more of the described parameter may be employed, without departing from the general scope or nature of the disclosure.

In exemplary embodiments related to the potential error detection method and associated systems of FIG. 2, the issue of wire error detection problem is formulated as an image classification problem. In some embodiments related thereto, a convolutional neural network-(CNN)-based binary image classifier is employed to slide over pre-processed wire segmentation images to determine whether the input image patch has any potential errors.

As noted above, since the sample size of the images processed (256×256) is significantly lower than a corresponding full image size image (8192×8192), designed features are composed to implicitly make use of global information. In particular with respect to embodiments related to FIG. 2, maximum horizontal extension values and vertical extension values of all pixels in a given wire segmentation image are calculated. The calculated horizontal and vertical extension values are then normalized into the [0, 255] range to form a Horizontal (H) feature 216 and a vertical (V) feature 210, respectively. The original wire segmentation image 204 is stacked with V and H features to form a three-channel image (e.g. an RGB image 222) (although other forms of stacked or unstacked images are hereby expressly considered) as the input 222 of the image classifier, as shown in FIG. 2.

With respect to image classification and the machine learning architectures and models associated therewith, and further with respect to those described in reference to FIG. 2, the following description may be interpreted in relation to the abbreviations further described below. In summary, the machine learning-based aspects of embodiments described with respect to FIG. 2 relate to composing a training set, W0, which was taken as a ground truth, while 256×256 image patches were randomly sampled from W1, W2, and W3 as training samples. Each image patch was labeled as positive/negative based on whether it had at least one electrically significant difference (ESD) with respect to the corresponding patch from W0. After visual inspection, it was found that two issues typically caused incorrect labels (i.e. error vs. non-error). The first issue arose from isolated pixels. The second issue related to pixels located at edges. Thus, all isolated pixels whose areas are lower than 25 pixels in W0, W1, W2, and W3 were removed. Further, the label of each sample's 192×192 central region (with borders of 32 pixels removed) was calculated. The sampled patch was kept only if both labels match, and, otherwise, the patch was discarded. On average, this led to approximately 10% of randomly sampled patches being discarded, in accordance with this non-limiting embodiment.

For the results presented in FIG. 2, a Resnet18 machine learning architecture was used as an image classifier. In this non-limiting embodiment the FC layer, which generated the final output 228, was modified to generate a binary output. Existing strategies known in the art may, in some embodiments, be implemented to train such a machine learning network. Input samples in this case were normalized from −1 to 1. As, in accordance with some embodiments, training sets may be unbalanced (e.g. positive samples may only account for, for example, approximately 3% of sample), a weighted cross-entropy loss may be used whose weights for positive and negative samples may be pre-defined. For example, and in accordance with some embodiments, such a loss function may be defined as N/(P+N) and P/(P+N), where P and N are numbers of positive and negative samples, respectively.

With respect to machine learning inference, the output of the exemplary image classifier of FIG. 2 was a two-element vector denoted as [p, n], where a positive detection was identified when p>n. In some embodiments, a threshold over classification results of highly overlapped patches within an area to localize errors may be applied. For instance, at a step size of 128, an area of 384×384 may extract four regular patches (e.g, wherein corresponding upper-left corner indices are [0, 0], [0, 128], [128, 0], [128, 128]). In some such cases, the common overlapping region may correspond with the central 128×128 region with upper-left corner indices [128, 128]. When the summed classification results of four patches are over the pre-set threshold, in accordance with some such embodiments, the central 128×128 region may be marked as an error. It will be appreciated that, in some embodiments, this post-processing step may be optional, and, for instance, applied for localising wire errors more precisely, as necessary or desired. Conversely, and in accordance with other embodiments, to detect whether a given sized (e.g. 256×256) patch contains errors, using the direct output of the image classifier may be sufficient.

With respect to, for example, wire error detection, as schematically illustrated in FIG. 2 for exemplary purposes, only, various training sets and/or evaluation parameters may be defined. For example, in and in accordance with some embodiments, two training sets in different sizes may be composed, denoted herein as ‘small’ and ‘large’, for exemplary purposes. In the example provided herein, a ‘small’ set consists of 229,049 samples with 6883 positive samples, while a ‘large’ set consisted of 1,030,699 training samples with 27833 positive samples. The testing set consisted of regularly sampled, nonoverlapping image patches from W0, W1, and W2, including 99 956 samples with 2437 positive samples. Six different models, corresponding to different input image encoding, network structures, training set sizes, and network structures, were trained. Experimental results are shown in Table 1. In Table 1, the label W corresponds with the machine learning analysis of only a wire segmentation result, VH refers to the analysis of extension arrays of V and H only, and WVH corresponds with the machine learning analysis of wire segmentation with V and H extension arrays. In this example, ‘tuning’ refers to the use of a ResNet18 network pre-trained on ImageNet, wherein only the last FC layer on the new training set was tuned.

TABLE 1
Wire detection performance of various trained models.

| | | Train | | | |
|---|---|---|---|---|---|
| Network | Input | set | Strategy | Recall | Precision |
| ResNet18 | W | small | From | 0.83 | 0.77 |
| | | | scratch | | |
| ResNet18 | VH | small | From | 0.83 | 0.64 |
| | | | scratch | | |
| ResNet18 | WVH | small | From | 0.84 | 0.79 |
| | | | scratch | | |
| ResNet34 | WVH | small | From | 0.82 | 0.76 |
| | | | scratch | | |
| ResNet18 | WVH | large | From | 0.92 | 0.93 |
| | | | scratch | | |
| ResNet18 | WVH | small | Tuning | 0.61 | 0.30 |

As seen from Table 1, the highest performance achieved, in accordance with one embodiment, corresponded with a recall/precision of 0.92/0.93 with Resnet18 trained on a ‘large’ set. In these examples, the input image was encoded with raw wire segmentation information and HV extension arrays (i.e. horizontal and vertical extension arrays, as described above), together. From Table 1, it may be observed various embodiments effectively detect wire segmentation errors without human intervention, in accordance with some embodiments.

Further from Table 1, it may be observed that, compared with other models, and in accordance with some embodiments, a larger training set can effectively lead to higher performance in error detection (e.g. as observed from Row 3 vs. Row 5). Further, the use of wire segmentation images together with V and H extension arrays can improve the detection performance (e.g. as observed from Row 3 vs. Row 1), in accordance with some embodiments. While using the V and H extension arrays, only, is not optimal for error detection in this particular example (Row 2 vs. Row 1), various embodiments may benefit from such systems and methods depending on, for example, the particular machine learning architecture employed, and/or the quality and/or nature of the images analysed.

Further from Table 1, it may be observed that, in general, a more complicated network structure with higher performance on general image classification may not always lead to higher error detection accuracy (e.g. Row 4 vs. Row 3). This may, for some applications, imply that error detection task relies more on low-level, local information, which can be well extracted by shallow neural networks, in accordance with some embodiments. It may further be observed that tuning a network that is pre-trained on ImageNet is not necessarily beneficial to achieve higher error detection performance (e.g. Row 6 vs. Row 3). This may, in accordance with some embodiments, indicate that wire error detection may rely more on low-level information. Accordingly, a user may, in some embodiments, select (or avoid) a given machine learning architecture and/or model associated therewith based on training with respect to high-level information on, for example, ImageNet.

While the foregoing description relates to the assessment of potential errors of a first error type from segmented images, described for exemplary purposes with respect to the assessment of potential errors in wire extraction from segmented SEM images, various embodiments may additionally, or alternatively, relate to the assessment of errors of a second error type from segmented images. For exemplary purposes, the foregoing description relates to the assessment of potential errors in the segmentation of vias from segmented SEM images. However, it will be appreciated that the assessment of such an error type may, in some embodiments, relate to the extraction of a second error type in addition to the assessment of potential errors of a first error type, or, in other embodiments, the identification of such errors may relate to an independent process or system from that described above with respect to a first error type. That is, the foregoing description may relate to a respective process or system, which may be performed independently from other processes, or may be performed in conjunction with another process to, for example, identify potential errors of a plurality of types.

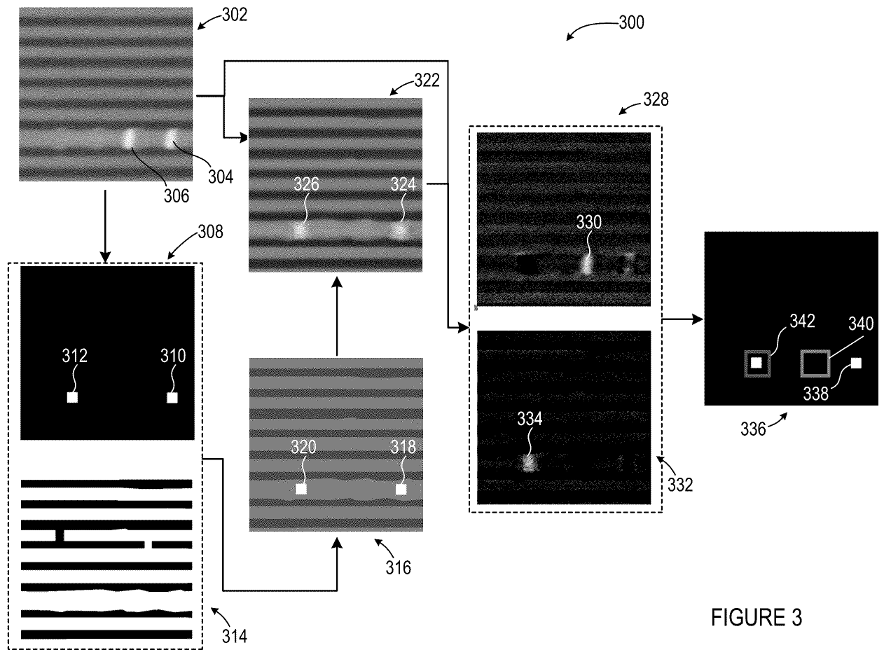

In accordance with some embodiments, FIG. 3 is a schematic of an exemplary process 300 for automatically detecting potential errors in segmented images. As described above with respect to the exemplary embodiment of FIG. 2, the method 300 of FIG. 3 may be executable by one or more digital data processors. For illustrative purposes, this example relates to the identification of potential errors in segmentation output of an SEM image with respect to identifying vias therefrom, although it will be appreciated that other object, image, and/or extraction types may be similarly applied, in accordance with other embodiments.

In the exemplary embodiment of FIG. 3, the process 300 relates to the analysis of various derivatives of an SEM image 302 of a region of an IC. While, generally, a process as herein described does not necessarily require the execution of obtaining such an image, it will be appreciated that some embodiments do indeed relate to the acquisition of the image 302, and/or subsequent processing thereof. It will further be appreciated that, generally, an SEM image 302 may comprise, for example, the entirety of a layer of an IC. However, and in accordance some embodiments, an SEM image 302, or more generally an input image 302, may comprise a portion of an image (e.g. an image patch or tile) that is defined based on, for example, a region of a corresponding IC layer or other substrate that may be realistically or practically imaged using an SEM or other imaging source for a given imaging configuration. For clarity and illustrative purposes, only, the non-limiting input image 302 corresponds with the SEM image 202 of the embodiment described above with respect to FIG. 2. However, it will be appreciated that the input image 302 may comprise, for example, an image or image patch from a different region of an IC, as, indeed, various embodiments relate to the processing of thousands of millions of such image patches for one or more layers of an IC.

As described above, a segmentation process may be performed to generate segmented images therefrom based on, for example, pixel intensity values in the input image 302. For example, in the exemplary process 300 of FIG. 3, the input image 302 is segmented as described above to provide respective segmentation images 308 and 314. In this non-limiting example, as the input image 302 corresponds with the input image 202 of FIG. 2, the segmented image 314 corresponds with the wire segmentation image 204 of FIG. 2. However, it will be appreciated that this particular example is provided for illustrative purposes, only, and that a segmented image 314 may comprise, for example, a different array of segmented pixel values 314, even if the input image 302 is processed to extract the same features (e.g. wires) as in the process 200. For example, while the segmented pixel values 204 for wire extraction may correspond with a segmented wire pixel value w₁, the corresponding segmentation array 314 in a process 300 may related to segmented wire pixel values of w₂. It will be appreciated that this may be the case even if, for instance, only a single object type (e.g. wires) are extracted from a segmentation process, as compared to a segmentation process is employed to extract multiple object types (e.g. both wires and vias) in the same extraction process, which may more naturally result in different segmentation values.

In the exemplary embodiment of FIG. 3, the input image 302 is also segmented to extract via features, as illustrated by the via segmentation output 308. In this non-limiting case, segmentation for both wires 314 and vias 308 is performed independently from the input image 302, and the segmentation results 308 and 314 accordingly relate to pixel values that may overlap or comprise the same values for respective features identified therein (e.g. both wire and via pixels may relate to a segmentation value of 1, while background in each case corresponds with a segmentation value of 0). However, it will be appreciated that, in some embodiments, both wires and vias may be extracted in a simultaneous segmentation process, wherein, for example, background pixels are segmented with a value of b, wires are extracted as pixel values of w, and via pixels are extracted as pixel values v. Accordingly, in some such embodiments, even the extraction of multiple object types may result in a segmentation output comprising a single segmented image or array of segmented pixel values.

As described above, wires pixels are shown in the segmented image 314 as bright pixels (white), while background corresponds with dark pixels (black). Similarly, via pixels in segmented images are shown as bright pixels (white) in via segmentation output 308, while background relates to dark (black) pixels. In this example, while the human may interpret the input image 302 as comprising two vias 304 and 306, the corresponding via segmentation output 308 shows a different set of two identified vias 310 and 312. If the interpretation of the input image 302 comprising vias 304 and 306 is taken as a ground truth, the segmentation output 308 then comprises at least one error. In particular, by visual inspection, while the via 304 appears to be accurately captured in the segmentation output 308 as the extracted via 310, the extracted via 312 appears to be a false positive, as it is disposed in the segmented image in a different area from the via 306 in the input image 302. Conversely, the segmentation output 308 does not appear to capture the via 306 from the input image 302.

As noted above, the segmentation output 308 and 314 may relate to a single output image, for instance one having a respective segmentation values for each of wires and vias, which may be subsequently processed. However, in the non-limiting embodiment of FIG. 3, the process 300 relates to generating a combined segmentation image 316 or stacked image 316 from the respective via and wire segmentation outputs 308 and 314. As, in this non-limiting case, respective segmentation images 308 and 314 relate to arbitrary values for positively identified via and wire pixels, the combined segmentation image 316 comprises an array of pixel values 316 in which respective via and wire pixels are defined in accordance with an assignment function.

That is, and in accordance with various embodiments, the non-limiting example of FIG. 3 relates to combining, in this case a plurality of segmented images 308 and 314, to a combined segmented image 316, wherein, during such combining, segmented values in the combined image 316 are digitally assigned to combined image pixel values 316 at least in part based on properties of the input image 302.

As noted above, a challenge with respect to such the tasks herein addressed, using conventional approaches, is a problematic variability in intensities between acquired images 302. That is, while a first SEM image of a first region of an IC may show wires having a pixel intensity w₁, a second SEM image, even if acquired from the same IC layer, may show wires as having a pixel intensity value w₂, wherein one of w₁ or w₂ is significantly greater than the other. This may complicate subsequent analysis processes, as automated approaches may perform poorly or lack reproducibility when the same extracted feature type is represented by significantly different segmentation values. This issue may be exacerbated when, for example, via pixels, which are typically much brighter than wires, are extracted from a relatively dark image, resulting in via pixel values that may be lower than, for example, wire pixels in another generally bright image. Accordingly, automated processes (e.g. machine learning-based recognition processes) may, for example, struggle to differentiate wires and pixels when segmented values assigned thereto are inconsistent between images.

Accordingly, and in accordance with various embodiments, the non-limiting example of FIG. 3 relates to assigning combined segmentation array values 316 based at least in part one or more properties of the input image 302, which may be variable between, for example, image patches acquired by an SEM and corresponding to different regions of an IC layer. In some embodiments related to the extraction of wires and vias from SEM images, an image property that may be utilised to assign segmentation values relates to an expected brightness, on an image-by-image basis, of respective wire and via pixels. That is, as vias are typically the brightest features in SEM images of IC layers, one assumption that may be made, in accordance with some embodiments, is that a via may generally be represented by the brightest 10% (or another percentile or like metric) of pixel values in an input image. Accordingly, and in accordance with some embodiments, a histogram or like metric of the pixel brightness values of an image may be used to define ultimate segmented values of vias in a combined image 316, wherein a value corresponding to the brightest X % (e.g. 5%, 10%, or the like) of the histogram, or a function thereof, defines the ultimate via pixel value in a segmented image.

For example, if the brightest 10% of pixel values of the SEM image 302 range from brightness values between 90 and 100 (arbitrary units), segmented via values in a combined image 316 (or indeed any segmentation output related to vias) may be assigned a value of, for example, 90. Similarly, for a generally brighter input image 302, wherein the brightest 10% of pixels correspond with values between 900 and 1000, via segmentation values may be assigned a value of, for example 900, or a value computed as a function thereof. In the example of FIG. 3, the segmented vias 310 and 312 are assigned the brightest values in the combined image 316, illustrated by the vias 318 and 320 shown in the combined image 316.

Similarly, wire values in a segmentation output 308 or combined image 316 may be assigned based on one or more properties of the input image 302. For example, as similarly described above with respect to vias, a wire may generally correspond to pixels of an SEM image 302 that are of medium or similar brightness relative to all pixels of the input image 302. Accordingly, in a histogram of brightness values of an input image 302, a wire may be expected to be represented by, for example, a median of brightness values. Thus, and in accordance with some embodiments, a wire pixel in a segmentation output 314 or combined image 316 may be assigned a value corresponding with the median brightness value in an input image 302. For example, this may relate to, for an input image 302 having brightness values between 0 and 100 and a median value of 50, assigning wire pixels a value of 50, or a function thereof. Similarly, for an input image varying in pixel values between 0 and 1000 and characterised by a median value of 500, wire pixels values may be assigned a value of 500, or a function thereof. However, it will be appreciated that such description is provided for exemplary purposes, only, and that other embodiments may relate to the assignment of segmentation values in one or more of a segmentation output 314 or combined image 316 in accordance with other parameters, such as an average of pixel brightness values in an input image, or in relation to a standard deviation from an average of pixel values, or a threshold or percentile, to name a few non-limiting examples.

Generally, while such aspects are not required for some embodiments, such assignment of values may provide for consistency in downstream processes. For example, by performing such a normalisation (i.e. assigning segmented values to normalised segmentation values based at least in part on pixel values associated with an input image) segmentation outputs 308 or 314, or again a combined segmentation image 316, may be readily compared to input images 302 in a downstream process, as the derived image (e.g. combined image 316) comprises segmentation values representative of the particular input image 302 from which it was derived, in accordance with some embodiments.

Moreover, it will be appreciated that, in accordance with some embodiments, raw segmentation outputs (e.g. segmented images 308 and 314) may be employed in the generation of a combined image 316. However, in accordance with other embodiments, one or more segmentation inputs may be, before combination, processed, for example to identify and/or correct errors detected therein. For example, a wire segmentation image 314 may first be processed as described above with respect to FIG. 2 to identify and correct errors, wherein a corrected segmentation image may be employed to provide a combined image 316, as is schematically illustrated in FIG. 3.

In the exemplary embodiment of FIG. 3, the process 300 comprises digitally translating, using a digital image-to-image translator and based at least in part on segmented pixel values and the input image 302, a segmented image to a reconstructed image 322. In this particular example, the combined segmentation image 316 is used as input for the image translator to generate the reconstructed image 322, wherein the image translator also received as input the original SEM image 302 from which the segmentation image 316 was ultimately derived. Accordingly, and as will be appreciated by the skilled artisan, the image translator received the segmented image 316 and attempted to construct a ‘realistic’ representation thereof based at least in part on the original image 302. Accordingly, and in accordance with various embodiments, a machine learning architecture (e.g. an image translator) may be employed to construct a more ‘realistic’ image from a processed version of the image being reconstructed, the results of which may be used, in some embodiments, for downstream processing.

It will be appreciated that various embodiments may relate to various machine learning architectures and/or models to perform such an image translation. In the non-limiting embodiment of FIG. 3, the architecture known as pix2pix was employed for generating the reconstructed image 322. However, other embodiments relate to the employ of variants of such an architecture (e.g. other adversarial network configurations), or indeed to other machine learning architectures or models.

To generate the reconstructed image 322 of FIG. 3, and with reference to the expanded abbreviations and definitions further described below, W0 was used as the wire segmentation image, and a training set of 39 936 image patches was employed (1024 patches per SEM image), which were randomly sampled from both of two via segmentation results, denoted as V0 and V1. In accordance with various embodiments, various training strategies may be employed, and it will be appreciated that the described strategy (e.g. number of training samples) is provided for non-limiting illustrative purposes, only. In the example shown, the following variations from established methods were employed: the number of input and output channels for pix2pix was set to 1 and the generator network was set to ‘unet_256’; all data augmentations were disabled and each 256×256 image was directly loaded and normalised into the network for training; and the total training epochs were set to 10. In the last five epochs, the learning rate decayed linearly.

As seen from the exemplary embodiment of FIG. 3, the reconstructed image 322 represents the two segmented vias 310 and 312 as reconstructed via features 324 and 326, respectively. In this case, the reconstructed image 322 is compared with the original input image 302 to identify regions of disparity therebetween. That is, as the combined segmentation image 316 was scaled to be representative of pixel intensity values of the input image 302, the reconstructed image 322 may be, in accordance with some embodiments, digitally compared to the image 302 to identify regions where pixels or pixel group differ (significantly) from ‘reality’ in the attempted reconstruction 322. In accordance with various embodiments, such differences or regions of disparity may be indicative of potential errors in the segmentation results of, for example, vias, as they may correspond with the falsely positive recognition of vias, or the absence of vias that should be identified in segmentation outputs.

To this end, various embodiments relate to the digital execution of a comparison of the reconstructed image 322 and the input image 302. For example, a comparison may comprise a computation of a difference between corresponding pixel values in the input image 302 and the reconstructed image 322, although other comparisons may be readily employed, in accordance with different embodiments. In the exemplary embodiment of FIG. 3, two exemplary comparisons are illustrated, wherein a first comparison corresponds to a subtraction of the reconstructed image 322 from the original image 302 (i.e. the pixel values of the original image minus the corresponding pixel values of the reconstructed image 322, or oSEM-rSEM), which results in the first difference image 328, while the second comparison corresponds with a subtraction of the original SEM image oSEM 302 from the reconstructed image rSEM 322, resulting in the second difference image 332.

In the first comparison output 328, and as expected from the above comparison description, the output result 328 highlights a via-like object 330 that corresponds with the via 306 that was missed during segmentation. Conversely, the second comparison output 332 highlights a via-like object 334 that corresponds with the segmented via 312 that did not appear to exist in the original SEM image. Accordingly, and in accordance with such embodiments, such comparisons may aid in the identification of, for example, false positives and missed features in segmentation processes.

In accordance with the exemplary embodiment of FIG. 3, the process 300 continues with the digital identification of regions of disparity between the reconstructed image 322 and the input image 302 in accordance with a designated comparison function. For example, in this embodiment, the comparison outputs 328 and 332 show bright regions 330 and 334 corresponding with potential errors in the via segmentation 308 used in the process. The digital identification of such potential errors may relate to defining, for example, regions of disparity 340 and 342, for instance via a digital classification process. Upon positively identifying such a region(s) of disparity, a corresponding error signal may be provided (e.g. boxes 340 and 342) in association with one or more of the segmented images used for processing. In this case, the error signal relates to the presentation of the via segmentation 336, which, while showing the correctly identified via 338 in the absence of an indication thereto, also highlights potential errors in the regions 340 and 342. In this case, the output image 336 corresponds with the via segmentation image 308 used to generate the reconstructed image 322, with indications provided with respect to identified regions of disparity 340 and 342, but not to the correctly identified via 338. As described above with respect to FIG. 2, it will be appreciated that such error signals may be provided in any number of ways based on, for example, the application at hand. For example, and without limitation, a signal may be provided as a listing of segmentation images 336 for which there is a suspected region of disparity 340 or 342, which may be presented to the user for subsequent (human) analysis.

In accordance with various embodiments, such digital identification of a region of disparity between reconstructed images 322 and input images 302 may be executed in accordance with a designated comparison function. In such contexts, and without limitation, a designated comparison function may relate to, for example, a threshold parameter corresponding to a size of an identified region of disparity (e.g. the size of boxed regions 340 and 342). Such a function may be beneficial to, for example, filter out from potential error identification large differences in pixel values that are highly localised (e.g. individual pixels, or small groups of pixels), which may correspond to noise rather than to a significant or functional difference in extracted layouts (e.g. a falsely identified via, or a via that was missed during segmentation). Additionally, or alternatively, a comparison function may relate to a characteristic metric of pixel values in a region of disparity, such as an average or like metric associated with pixels in, for example, an identified region of disparity 340 or 342. For example, it may be required that an average of pixel values in an identified region be above a threshold value, wherein regions having an average below the threshold may be filtered from subsequent processing and/or reporting, as it likely does not correspond with a significant difference with respect to a via. In accordance with yet other embodiments, a comparison function may relate to a shape of an identified region of disparity. For example, while the identified regions 340 and 342 of FIG. 3 are relatively square, more eccentrically defined regions may be interpreted as not corresponding to a significant error (e.g. an extra or omitted via), and may accordingly be filtered out from future consideration, in accordance with some embodiments. Regardless of the function(s) applied, it will be appreciated that some embodiments may relate to filtering from, for example, reporting one or more regions of disparity based at least in part on a designated comparison function applied. Moreover, various additional parameters may be considered in any such filtering or reporting processes. For example, and in accordance with some embodiments, a region in an output image 336 may be marked and/or identified as potential errors (e.g. extra or missing vias) if it does or does not overlap with any vias in an original segmentation image 308.

It will be appreciated that, in accordance with different embodiments, different approaches may be applied to the identification of regions of disparity. For example, while the embodiment of FIG. 3 relates to classifying images to define and report regions 340 and 342 based on a connected component analysis, the nature of which will be appreciated by the skilled artisan. However, it will be appreciated that other processes or systems known in the art may be applied, in accordance with other embodiments.

With respect to the exemplary embodiment of FIG. 3, it will be appreciated that various configurations may be applied in the context of machine learning architectures and/or training. For example, for the illustrated embodiment, V0 and V1 were taken as the ground truth and error set for testing. The labels of vias were assigned as discussed above, and pairs of segmentation images with no differences were omitted from future consideration.

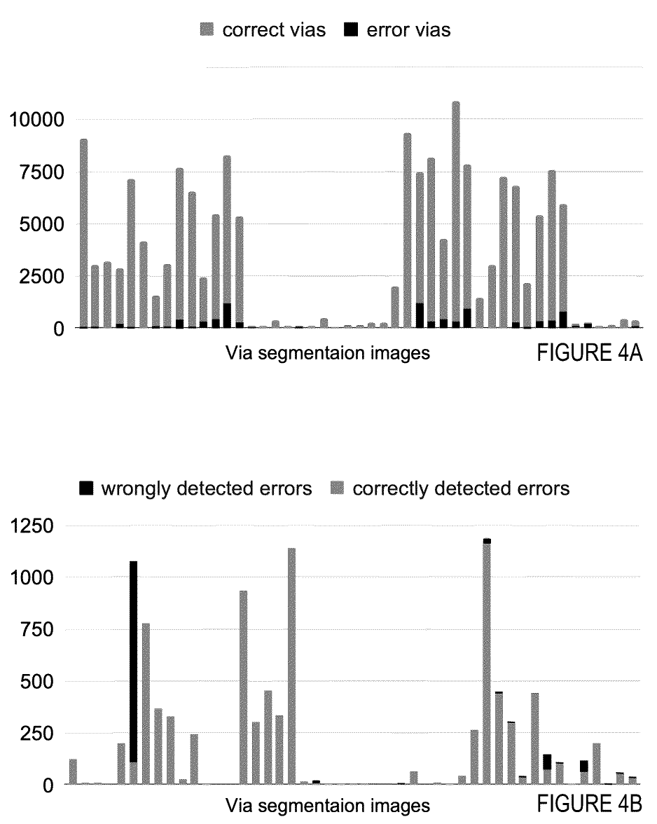

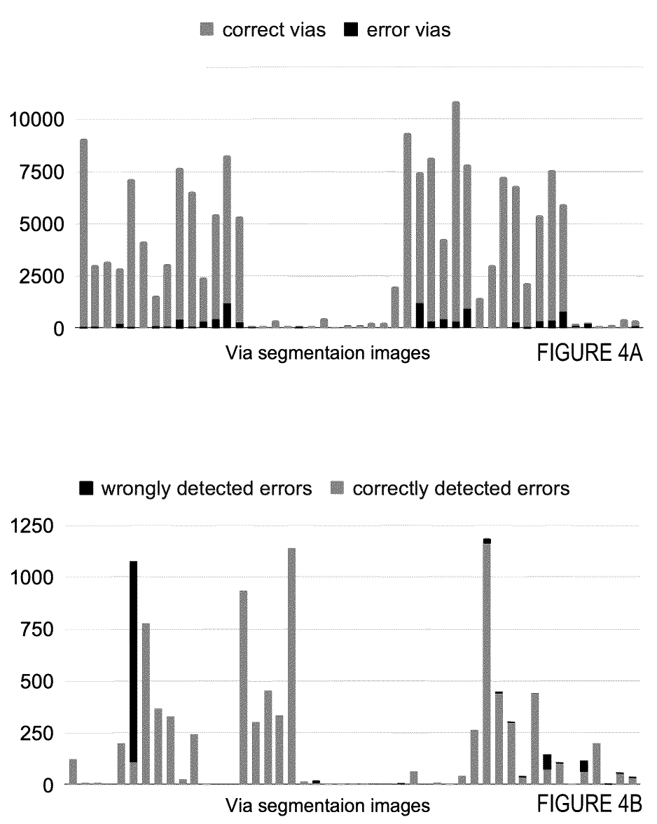

With respect to performance results, exemplary statistics corresponding to the particular embodiments herein described are presented in FIG. 4A, which shows an exemplary distribution of via errors in a testing set. In this example, reconstructed SEM image sets 322 (herein also denoted as R0 and R1) of V0 and V1 were used for evaluation, rather than the original SEM image set S0, as neither of V0 and V1 comprises the actual ground truth of S0. Exemplary experimental results are shown in FIG. 4B, wherein wrongly detected errors are either actual errors that are not detected (false negatives), or errors that are identified but do not correspond with actual errors (false positives).

Generally, various embodiments herein described provide for an automatic error detection approach for segmented images (e.g. SEM images of IC circuits, for example). While embodiments explicitly described herein relate to two error detection problems, namely wire error detection and via error detection, which are addressed using image classification and image translation, respectively, it will be appreciated that other approaches may be employed to address different error detection problems, without departing from the general scope and nature of the disclosure.

It is further noted that, in the embodiments explicitly described herein, the concepts of which may be applied in other contexts, the approaches employed resulted in recall/precision of 0.92/0.93 for wire error detection, and 0.96/0.90 for via error detection. Such embodiments, among other aspects, significantly mitigate major bottlenecks for automatic SEM image segmentation approaches, as proven by the evaluation herein described as applied to real industrial datasets applicable in real-world scenarios.

With respect to the particular examples presented herein, which are provided for exemplary purposes, only, 39 SEM images of various hardware components were acquired, including those related to one or more of a microprocessor, Radio Frequency (RF) transceiver, power management, flash memory, SoC, and the like. Images were acquired with, in these non-limiting examples, 2.92 nm average pixel size and 22.96 μm average field size. The collecting dwelling time for examples herein reported is 0.2 us/pixel. Each image was acquired in grayscale of size 8192×8192. SEM image sets may be generally denoted herein as S0, while, for exemplary purposes, two types of objects for segmentation are reported, namely vias and wires. Generally, vias comprise electrical connections between copper layers in ICs, which are often imaged to produce the highest pixel intensity, and are generally seen as small circles or rounded rectangles. Wires are often, as described above, imaged to produce lower pixel intensities than vias, but higher than the background. With respect to SEM imaging, four wire segmentation sets were acquired, denoted as W0, W1, W2, and W3, while two via segmentation sets were acquired, denoted as V0 and V1.

In the context of SEM image segmentation of ICs, and for exemplary purposes, only, only segmentation errors that cause differences in connectivity of IC layouts are defined as errors. These may be reported as electrically significant differences, or ESDs. In particular, for some of the embodiments herein described, for wire objects, an error may be identified if a segmentation result causes an ‘open’ or a ‘short’ that differs from a ground truth connectivity. For via objects, and as reported herein, an error refers to a via that is completely missed in segmentation, or defined where/when one is not present with respect to an actual via, as defined in a ground truth example. However, it will be appreciated that such concepts, as well as variants thereof, may be similarly applied, for example, to the classification or other processing of other object types from other forms of images.

As referred to herein, the following metrics may be used to quantify error detection. For wire segmentation ‘errors’, given a wire segmentation result EW and the corresponding ground truth segmentation result GW, the number of electric significant differences (ESD) between GW and EW may be calculated. For exemplary purposes, the number of ESDs is defined as the number of identified errors in EW. For via segmentation errors, given a via segmentation result EV and a corresponding ground truth segmentation result GV, all isolated regions from both EV and GV were extracted using known methods. Subsequently, each region from EV that has at least one pixel overlapping with a region from GV is treated as a correctly segmented via in the non-limiting embodiments herein described. Other regions from either EV or GV that have no overlapping region from the corresponding image are considered as errors of EV (corresponding to extra vias and missed vias, respectively).

As noted above, the resolution of raw SEM images (e.g. 8192×8192) may be too high for, for example, common CNN-based image processing approaches. Accordingly, and in accordance with some embodiments, images may be first processed in accordance with image patches (e.g. 256×256), which may then be digitally merged to form full-size results (e.g. for segmentation, defining extension arrays, and the like).

While the present disclosure describes various embodiments for illustrative purposes, such description is not intended to be limited to such embodiments. On the contrary, the applicant's teachings described and illustrated herein encompass various alternatives, modifications, and equivalents, without departing from the embodiments, the general scope of which is defined in the appended claims. Except to the extent necessary or inherent in the processes themselves, no particular order to steps or stages of methods or processes described in this disclosure is intended or implied. In many cases the order of process steps may be varied without changing the purpose, effect, or import of the methods described.

Information as herein shown and described in detail is fully capable of attaining the above-described object of the present disclosure, the presently preferred embodiment of the present disclosure, and is, thus, representative of the subject matter which is broadly contemplated by the present disclosure. The scope of the present disclosure fully encompasses other embodiments which may become apparent to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims. Moreover, no requirement exists for a system or method to address each and every problem sought to be resolved by the present disclosure, for such to be encompassed by the present claims. Furthermore, no element, component, or method step in the present disclosure is intended to be dedicated to the public regardless of whether the element, component, or method step is explicitly recited in the claims. However, that various changes and modifications in form, material, work-piece, and fabrication material detail may be made, without departing from the spirit and scope of the present disclosure, as set forth in the appended claims, as may be apparent to those of ordinary skill in the art, are also encompassed by the disclosure.

1. A method for automatically detecting potential errors in segmented images, the method executable by one or more digital data processors and comprising:
receiving as input a segmented image comprising an array of segmented pixel values each calculated in respect of a corresponding portion of an image;
for each of at least one respective dimension of said array, calculating a respective extension array comprising, for each given pixel of said array corresponding with a designated segmentation value, a corresponding extension value representative of an extension of said designated segmentation value in said respective dimension in said array of segmented pixel values;
based at least in part on said array of segmented pixel values and each said respective extension array, identifying, via a digital image classifier and a trained error detection model accessible thereto, a potential error in said segmented image; and
upon positively identifying said potential error, providing a corresponding error signal in association with said segmented image.

2-33. (canceled)

34. The method of claim 1, comprising defining, from each of said array of segmented pixel values and at least one said respective extension array, a corresponding sub-array corresponding with a designated sub-region of said image, wherein said identifying a potential error is digitally executed based at least in part on each said sub-array.

35. The method of claim 34, wherein said providing a corresponding error signal comprises providing said corresponding error signal in association with said corresponding sub-array defined from said array of segmented pixel values.

36. The method of claim 1, wherein said image comprises one or more of a non-optical microscopy image, an electric microscopy image, or a scanning electron microscope (SEM) image.

37. The method of claim 36, wherein one or more of said segmented pixel values or said designated segmentation value corresponds to one or more of a background, a wire, or a via.

38. The method of claim 37, wherein said designated segmentation value corresponds with a pixel value associated with a wire in an SEM image.

39. The method of claim 1, wherein said array of segmented pixel values comprises a two-dimensional array, and wherein said at least one respective dimension of said array comprises both dimensions of said two-dimensional array.

40. The method of claim 1, wherein said extension of said designated segmentation value corresponds with one or more of a number of continuous pixels in said respective dimension sharing said designated segmentation value and comprising said given pixel, or a function thereof.

41. The method of claim 1, wherein said corresponding extension value comprises a normalised extension value representative of said extension of said designated segmentation value normalised by a maximum extension value in said respective extension array.

42. The method of claim 1, further comprising digitally stacking said array of segmented pixel values and each said respective extension array as a digital representation thereof, wherein said identifying a potential error in said segmented image is executed at least in part based on said digital representation.

43. The method of claim 42, wherein said digital representation comprises a three-layer image stack.

44. The method of claim 1, wherein said digital image classifier comprises a machine learning architecture.

45. The method of claim 44, wherein said machine learning architecture comprises a ResNet-based architecture.

46. The method of claim 1, wherein said identifying a potential error in said segmented image comprises post-processing outputs of said digital image classifier corresponding with respective segmented images corresponding with respective patches of said image, wherein said post-processing comprises detecting error values in relation to a threshold when applied to at least partially overlapping outputs.

47. The method of claim 46, wherein said corresponding error signal is provided in association with an overlap region of said at least partially overlapping outputs.

48. A method for automatically detecting potential errors in segmented images, the method executable by one or more digital data processors and comprising:
receiving as input at least one segmented image each comprising a respective array of segmented pixel values each calculated in respect of a corresponding portion of an input image;
based at least in part on said segmented pixel values and said input image, digitally translating, using a digital image-to-image translator, said at least one segmented image to a reconstructed image;
digitally executing a comparison of said reconstructed image and said input image;
based at least in part on said comparison, digitally identifying a region of disparity between said reconstructed image and said input image in accordance with a designated comparison function; and
upon positively identifying said region of disparity, providing a corresponding error signal in association with one or more of said at least one segmented image.

49. The method of claim 48, wherein said at least one segmented image comprises a plurality of segmented images.

50. The method of claim 49, comprising digitally combining said plurality of segmented images to a combined segmented image, wherein said digitally translating comprises digitally translating said combined segmented image to said reconstructed image.

51. The method of claim 48, comprising digitally assigning said segmented values to normalised segmentation values based at least in part on pixel values associated with said input image, wherein said digitally translating comprises digitally translating said at least one segmented image to a reconstructed image based at least in part on said normalised segmentation values.

52. A method for automatically detecting potential errors in segmented images, the method executable by one or more digital data processors and comprising:
receiving as input at least one segmented image each comprising a respective array of segmented pixel values each calculated in respect of a corresponding portion of an input image;
identifying a first error type by:
for a given one of said at least one segmented image, calculating an extension array in at least one dimension of said respective array of segmented pixel values; and
based at least in part on said given segmented image and said extension array, identifying, via a digital image classifier and a trained error detection model accessible thereto, a potential error in said given segmented image;
identifying a second error type by:
digitally translating, using a digital image-to-image translator, said at least one segmented image to a reconstructed image; and
digitally executing a comparison of said reconstructed image and said input image to digitally identify therefrom a region of disparity therebetween in accordance with a designated comparison function; and
upon positively identifying one or more of said region of disparity or said potential error, providing a corresponding error signal in association with a corresponding one or more of said at least one segmented image.
